(19) United States
(12) Patent Application Publication
(10) Pub. No.: US 2006/0225917 A1
(43) Pub. Date: Oct. 12, 2006

(54) Conductive bump structure of circuit board and fabrication method thereof

(76) Inventor: Wen-Hung Hu, Hsin-chu (TW)

Correspondence Address: Mr. Joseph A. Sawyer, Jr;SAWYER LAW GROUP LLP, Embarcadero Corporate Center, Suite 406, 2465 East Bayshore Road, Palo Alto, CA, 94303, US

(21) Appl. No.: 11/360,099

(22) Filed: Feb. 22, 2006

(30) Foreign Application Priority Data
Apr. 11, 2005 (TW) 094111289

(51) Int. Cl. H05K 1/09; H05K 3/12

(52) U.S. Cl. 174/257; 29/842

(57) ABSTRACT

A conductive bump structure of a circuit board and a fabrication method thereof are proposed. The circuit board is formed with conductive circuits on a surface thereof An insulating protection layer having a plurality of openings to expose terminals of the conductive circuits is formed on the circuit board. A conductive layer is formed on the insulating protection layer and in the openings thereof. A patterned resist layer is formed on the conductive layer and has a plurality of openings corresponding in position to the terminals of the conductive circuits. Conductive bumps are formed by electroplating in the openings of the resist layer. Then, the resist layer and the conductive layer underneath the resist layer are removed. An adhesive layer is formed on the conductive bumps and completely covers exposed surfaces of the conductive bumps respectively. The circuit board can be electrically connected to electronic elements through the conductive bumps.

### FIELD OF THE INVENTION

The present invention relates to fabrication methods of conductive bump structures of circuit boards, and more particularly, to a conductive bump structure of a circuit board for electrical connection with an external device, and a fabrication method of the conductive bump structure by electroplating.

### BACKGROUND OF THE INVENTION

Compared with the wire bond technique, the flip-chip package proposed by IBM Inc. in 1960 uses solder bumps instead of golden wires to electrically connect a semiconductor chip with a substrate, thereby increasing package density, reducing package size and enhancing electrical performance. According to these advantages, a control-collapse chip connection (C4) is proposed which applies high temperature solder on a ceramic substrate.

According to the current flip-chip technique, a semiconductor IC chip surface is provided with electrode pads and correspondingly, a circuit board is provided with electrically connecting pads. Solder bumps or other conductive adhesive materials are suitably disposed between the chip and the circuit board. The chip is disposed with its active face down on the circuit board and electrically connected with the circuit board by the solder bumps or conductive adhesive materials.

As shown in FIG. 1, a plurality of metal bumps 11 are formed on the electrode pads 12 of a chip 13 and a plurality of pre-solder bumps 14 made of solder material are formed on the electrically connecting pads 15 of a circuit board 16. At a temperature sufficient to melt the pre-solder bumps 14, the pre-solder bumps 14 are reflowed on the corresponding metal bumps 11 to form solder joints 17. Subsequently, an underfill material 18 is used to fill the gap between the chip 13 and the circuit board 16, which provides a buffer effect to ensure the electrical connection integrity and reliability between the chip 13 and the circuit board 16.

Moreover, to electrically connect the subsequently packaged circuit board and chip to external electrical components, a plurality of solder balls need to be planted at the bottom surface of the circuit board. To provide effective electrical connection, solder material needs to be pre-disposed.

The method that is usually used to deposit solder material on electrically connecting pads of a circuit board is stencil printing technique. As shown in FIG. 2, a solder mask layer 21 is formed on a circuit board 20 with conductive circuits, the solder mask layer 21 having a plurality of openings to expose electrically connecting pads 22. A stencil 23 having a plurality of openings 23a is disposed on the solder mask layer 21 of the circuit board 20 such that solder material can be deposited on the electrically connecting pads 22 through the openings 23a by using a roller 24 or a spraying method. After the stencil 23 is removed, the deposited solder material is further reflowed to form solder structure on the electrically connecting pads 22.

However, with reduced size and increased input/output terminals of semiconductor chips, the area of chip carriers is becoming smaller and the number of electrically connecting pads is increasing. Thus, both the size of the electrically connecting pads and the spacing between the electrically connecting pads need to be reduced. With reduced size of electrically connecting pads, size of the stencil openings need to be reduced correspondingly, which not only results in high fabrication cost, but also makes the solder material difficult to pass through.

Furthermore, as the solder material is viscose, the more frequent performances of stencil printing leave more the solder material remaining on the inner walls of the stencil openings, which would make the amount and shape of the solder material in subsequent printing processes not match the predetermined design. As a result, the stencil needs to be cleaned after certain times of printing.

To overcome the above drawbacks, an electroplating method is proposed to form conductive bumps on electrically connecting pads of a circuit board, as shown in FIGS. 3A to 3G.

Referring to FIG. 3A, an insulating layer 31 is formed on a circuit board 30 with electrically connecting pads 301 and conductive circuits 302 formed on one surface thereof, the insulating layer 31 having a plurality of openings 310 to expose the electrically connecting pads 301.

Referring to FIG. 3B, a thin metal layer 32 is formed on surface of the insulating layer 31 and the openings 310.

Referring to FIG. 3C, an electroplated resist layer 33 is formed on the thin metal layer 32, which has openings 330 to expose the thin metal layer 32 on the electrically connecting pads 301.

Referring to FIG. 3D, an electroplating process is performed to form conductive bumps 34 on the electrically connecting pads 300.

Referring to FIGS. 3E and 3F, the resist layer 33 and the thin metal layer 32 underneath the resist layer 33 is removed.

Referring to FIG. 3G, a protection layer 35 is formed on surface of the conductive bumps 34.

Although the above electroplating method overcomes the drawbacks caused by the stencil printing method, it is difficult to align the openings 330 with the center of openings 310 because the size of the openings 310 (D1) and the size of the openings 330 (D2) formed by exposure and development are very fine while the registration resolution of a common machine only can reach 20 to 30 micrometers. Thus, the size of the openings 330 (D2) is usually enlarged to reduce the registration difficulty and resolution.

Moreover, to directly form openings 310 on the electrically connecting pads 301, the size of the electrically connecting pads 301 (D3) is made larger than that of the openings 310 (D1) of the insulating layer 31. To effectively attach the conductive bumps 34 to the electrically connecting pads 301, the size of the openings 310 (D1) can not be too small. As a result, the size of the electrically connecting pads 301 (D3) is not easy to be reduced, which accordingly cannot meet the requirement of fine pitch circuit.

In the above electroplating process, to achieve fine pitch conductive bumps, the registration resolution needs to be enhanced, thereby increasing fabrication complexity, fabrication time and registration difficulty. Therefore, the electroplating process can not effectively form fine pitch conductive bumps on electrically connecting pads.

In addition, with reduced size of electrically connecting pads, the area of electrically connecting pads exposed by the insulating layer becomes smaller. As a result, contact area between the conductive material subsequently deposited on the electrically connecting pads and the electrically connecting pads is reduced, which result in insufficient bonding force between the conductive material and the electrically connecting pads. Meanwhile, the solder material is easy to flash during the reflow process because of insufficient support strength of the solder material. Moreover, to ensure electrical connection between the electrically connecting pads and external electronic devices, a large amount of solder material would be used, which increases fabrication cost and prolongs fabrication time.

### SUMMARY OF THE INVENTION

In light of the above drawbacks of the prior art, an objective of the present invention is to provide a conductive bump structure of a circuit board and a fabrication method thereof, which can avoid the prior art drawbacks such as size and spacing limitations of the conductive bump structure and registration difficulty.

Another objective of the present invention is to provide a conductive bump structure of a circuit board and a fabrication method thereof, which can reduce fabrication time and simplify fabrication processes.

Still another objective of the present invention is to provide a conductive bump structure of a circuit board and a fabrication method thereof, which can increase the bonding force and pushing/pulling forces between the conductive bump structure and the circuit board.

A further objective of the present invention is to provide a conductive bump structure of a circuit board and a fabrication method thereof, which can form the conductive bump structure on a fine pitch conductive circuit.

A further objective of the present invention is to provide a conductive bump structure of a circuit board and a fabrication method thereof, which can avoid the drawbacks of the stencil printing technique.

A further objective of the present invention is to provide a conductive bump structure of a circuit board and a fabrication method thereof, which can reduce the use of solder material.

To achieve the above and other objectives, the present invention discloses a fabrication method of a conductive bump structure of a circuit board, comprising: providing a circuit board with conductive circuits on at least one surface thereof and forming an insulating protection layer with a plurality of openings to expose terminals of the conductive circuits on the circuit board; forming a conductive layer on the insulating protection layer and surface of the openings; forming a resist layer on the conductive layer, the resist layer having a plurality of openings to expose the conductive layer corresponding to the terminals of the conductive circuits; and forming conductive bumps by electroplating in the openings of the resist layer corresponding to the terminals of the conductive circuits. Therein, the fabrication method further comprises removing the resist layer and the conductive layer underneath the resist layer and forming an adhesive layer on the conductive bumps, which completely covers exposed surface of the conductive bumps. Alternatively, the adhesive layer can be formed first on upper surface of the conductive bumps by electroplating and then the resist layer and the conductive layer underneath the resist layer are removed.

The present invention also discloses a conductive bump structure of a circuit board formed through the above fabrication method, the conductive bump structure comprising: conductive bumps formed on terminals of conductive circuits on surface of a circuit board; and an adhesive layer formed on the conductive bumps.

Compared with the prior art that forms conductive bumps on electrically connecting pads, the present invention forms fine pitch conductive bumps on terminals of conductive circuits, thereby avoiding the prior art drawbacks such as fabrication difficulty due to high requirement of registration and difficulty of forming fine pitch conductive bumps when the registration resolution is reduced. In addition, because the conductive bumps of the present invention completely cover the terminals, contact area between the conductive bump structure and the terminals is increased, thereby increasing the bonding force and pulling/pushing forces between the conductive bumps and the circuit board. Meanwhile, by using low cost copper as electroplating material and reduce the use of solder material, the material cost is reduced. Moreover, by reducing the use of solder material, the present invention prevents the occurrence of bridge and short circuit effect.

### BRIEF DESCRIPTION OF DRAWINGS

The present invention can be more fully understood by reading the following detailed description of the preferred embodiments, with reference made to the accompanying drawings, wherein:

FIG. 1 (PRIOR ART) is a cross-sectional diagram of a conventional flip-chip component;

FIG. 2 (PRIOR ART) is a cross-sectional diagram showing a conventional stencil printing process for deposition of solder material on electrically connecting pads of a circuit board;

FIGS. 3A to 3G (PRIOR ART) are cross-sectional diagrams showing steps of a conventional fabrication method of a conductive bump structure of a circuit board;

FIGS. 4A to 4I are cross-sectional diagrams showing steps of a fabrication method of a conductive bump structure of a circuit board according to the present invention; and

FIG. 4I′ is a cross-sectional diagram of a conductive bump structure of a circuit board according to another embodiment of the present invention.

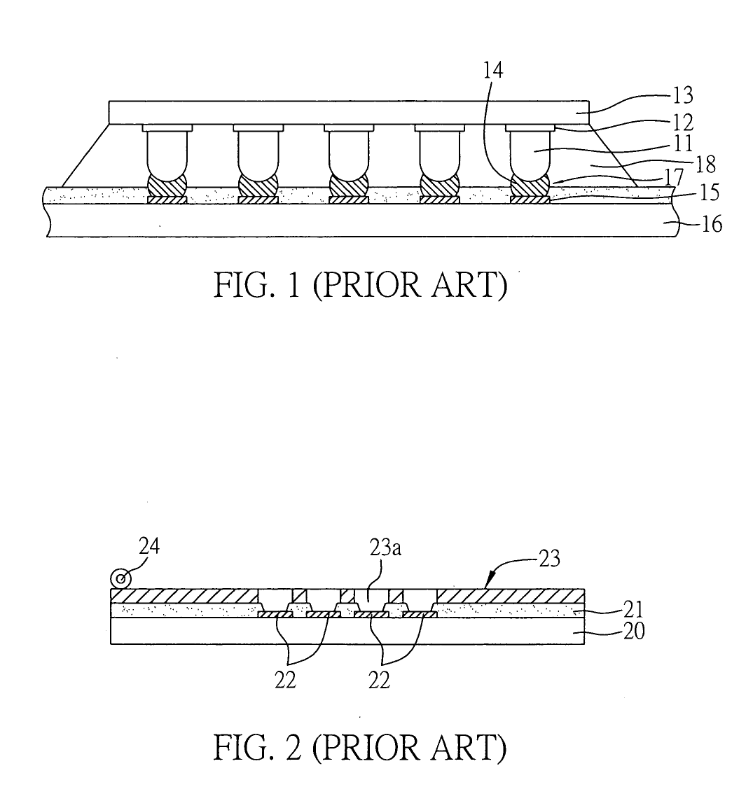

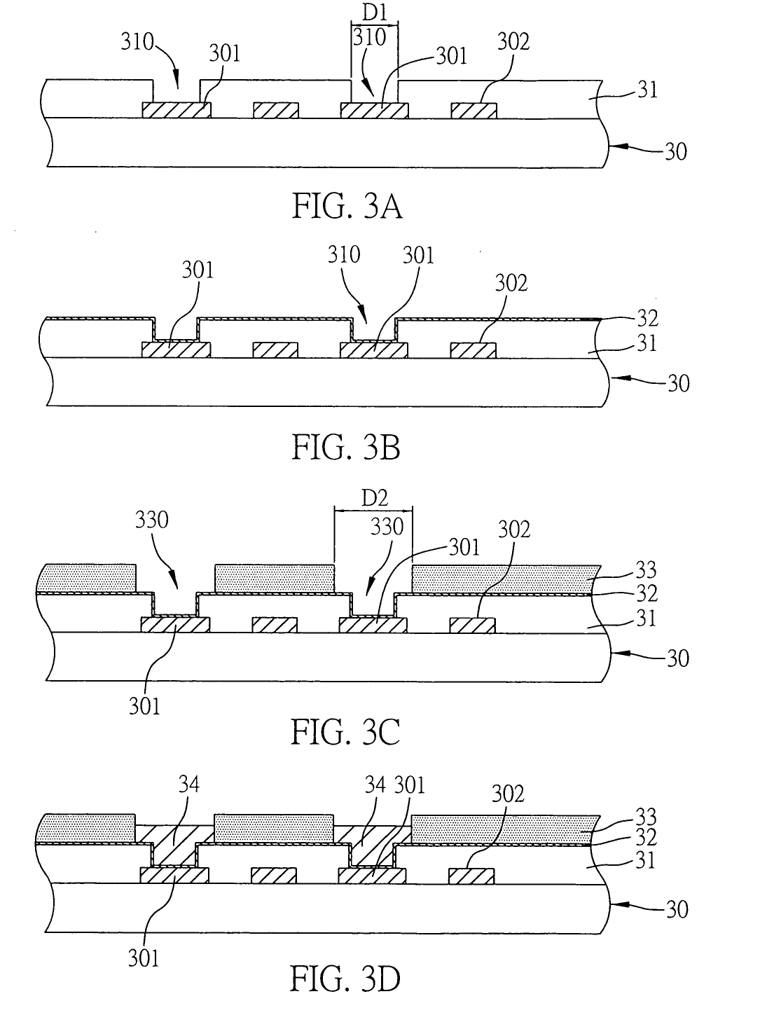

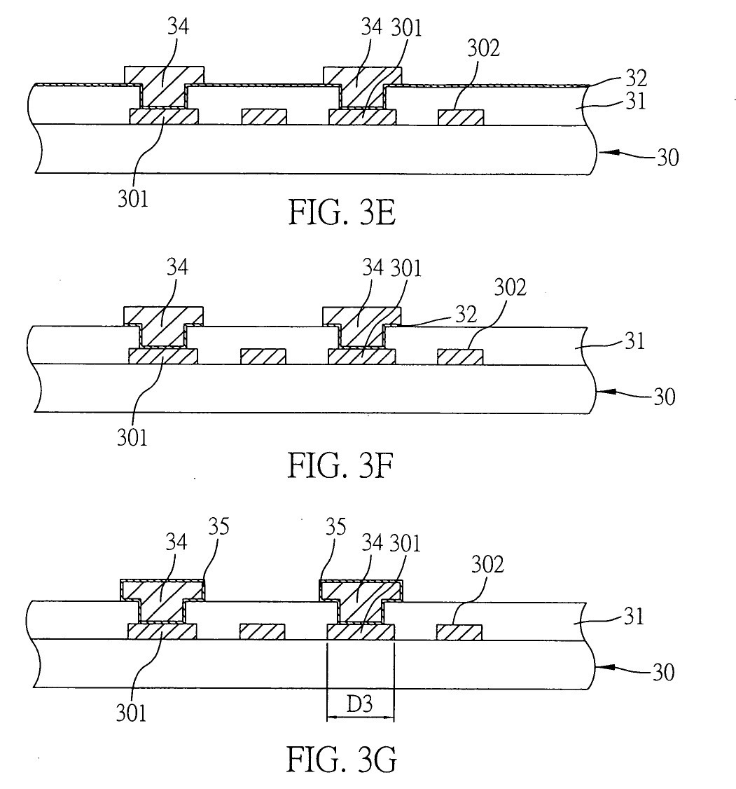

### DETAILED DESCRIPTION OF PREFERRED EMBODIMENTS

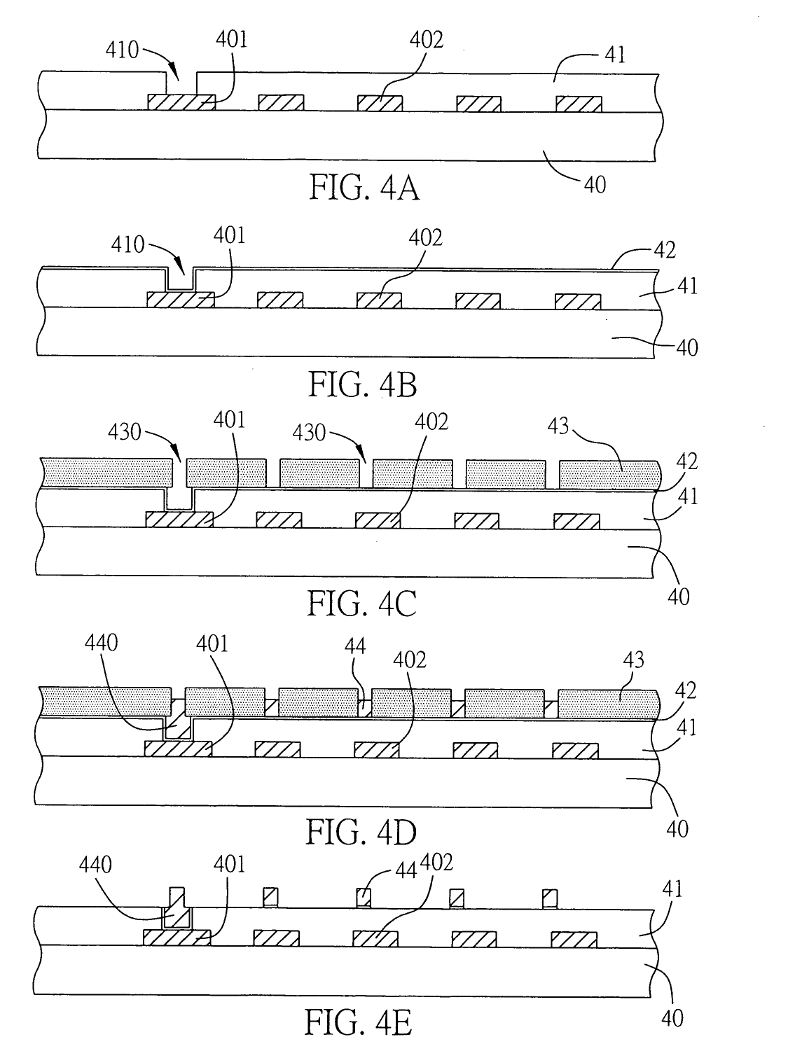

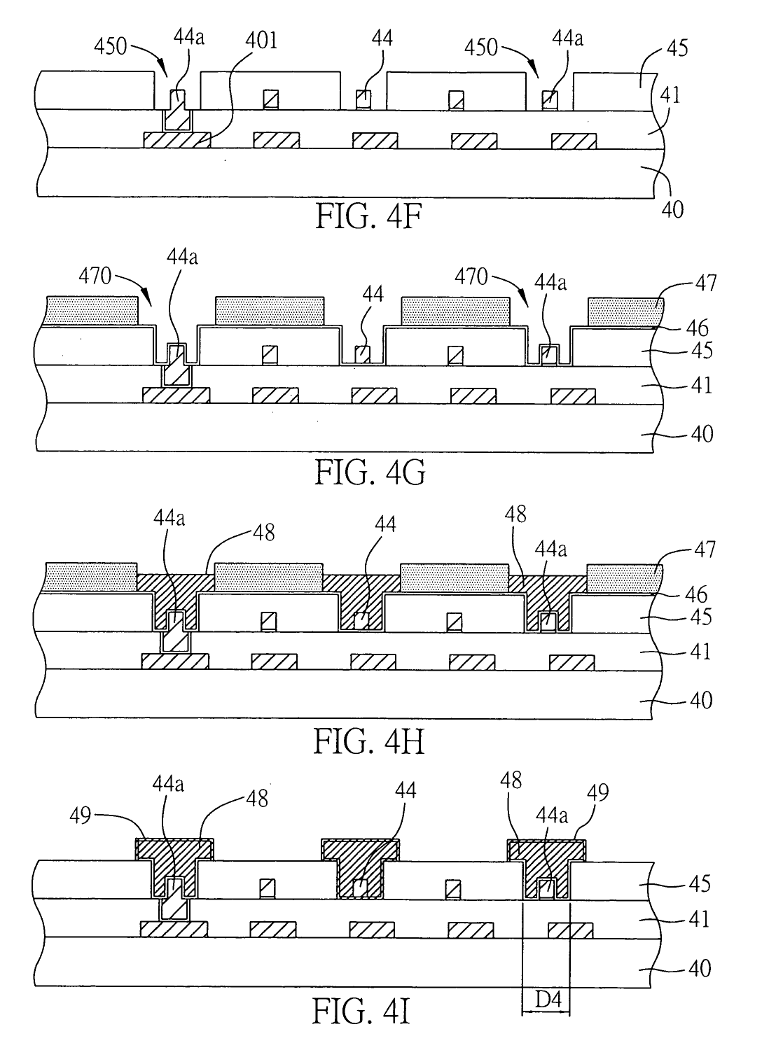

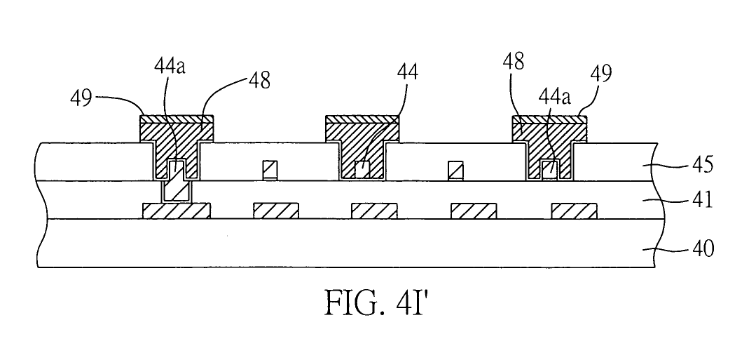

Embodiments of a conductive bump structure of a circuit board and a fabrication method thereof proposed in the present invention are described with reference to FIGS. 4A to 4I and 4I′.

FIGS. 4A to 4I show a fabrication method of a conductive bump structure of a circuit board according to the present invention. It should be noted that the drawings only show basic construction related to the present invention.

Referring to FIG. 4A, an insulating layer 41 is formed on a core circuit board 40 with electrically connecting pads 401 and conductive circuits 402 formed on one surface thereof, the insulating layer 41 having a plurality of openings 410 to expose the electrically connecting pads 401.

Referring to FIG. 4B, a conductive layer 42 is formed on the insulating layer 41 and surface of the openings 410 to function as a current conductive path in subsequent electroplating process. The conductive layer 42 can be a metal layer or several laminated metal layers formed of copper (Cu), tin (Sn), nickel (Ni), chromium (Cr), titanium (Ti), Cu/Cr alloy or tin/lead (Sn/Pb) alloy. Alternatively, the conductive layer 42 can be formed of conductive polymer material such as polyacetylene, polyanion or organic sulphur polymer.

Referring to FIG. 4C, a resist layer 43 is formed on the conductive layer 42 by such as attaching, which can be a photoresist layer such as a dry film layer or a liquid photoresist layer. Then, the resist layer 43 is patterned by exposure and development to form a plurality of openings 430 to partially expose the conductive layer 42. At least one of the openings 430 corresponds in position to the electrically connecting pads 401. The size of the openings 430 is smaller than that of the openings 410.

Referring to FIG. 4D, by using the conductive layer 42 as a current conductive path, an electroplating process is performed to form conductive circuits 44 in the openings 430 of the resist layer 43 and conductive vias 440 in the openings 410 of the insulating layer 41, wherein the conductive vias 440 electrically connect the conductive circuits 44 with the electrically connecting pads 401 in the lower layer.

Referring to FIG. 4E, the resist layer 43 and the conductive layer 42 underneath the resist layer 43 are removed. The process is a prior art and detailed description of it is omitted.

Referring to FIG. 4F, an insulating protection layer 45 is formed and then patterned by exposure and development to form a plurality of openings 450 to expose the terminals 44a of the conductive circuits 44. Therein, the insulating protection layer 45 can be made of solder mask material such as green paint. The size of the openings 450 is larger than that of the terminals 44a while smaller than that of the electrically connecting pads. The terminals 44a is completely exposed by the openings 450 to facilitate subsequent electroplating process on the fine pitch conductive circuits, thereby forming fine pitch conductive bumps on the terminals of the fine pitch conductive circuits.

Referring to FIG. 4G, a conductive layer 46 is formed on the insulating protection layer 45 and surface of the openings 450 to function as current conductive path in subsequent electroplating process. The conductive layer 46 can be made of a metal, an alloy or several laminated metal layers or conductive polymer material. Then, a resist layer 47 is formed on the conductive layer 46 and patterned to form a plurality of openings 470 corresponding in position to the terminals 44a.

Referring to FIG. 4H, by using the conductive layer 46 as current conductive path, an electroplating process is performed to form conductive bumps 48 in the openings 470 of the resist layer 47. As a result, the fine pitch conductive bumps 48 are formed on the terminals 44a of the fine pitch conductive circuits. Therein, the conductive bumps 48 can be made of Cu, Sn, Ag, Pb or alloy thereof. Preferably, the conductive bumps 48 are made of low cost copper (Cu).

Referring to FIG. 4I, the resist layer 47 and the conductive layer 46 underneath the resist layer 47 are removed. Then, an adhesive layer 49 is formed on the conductive bumps 48, the adhesive layer 49 completely covering exposed surface of the conductive bumps 48. The adhesive layer 49 can be made of Cu, Sn, Pb, silver (Ag), Ni, gold (Au), platinum (Pt), phosphorus (P) or alloy thereof. Alternatively, the adhesive layer 49 can be formed of an organic solderability preservative (OSP).

Alternatively, before removing the resist layer 47 and the conductive layer 46 underneath the resist layer 47, an electroplating process is performed to form an adhesive layer 49 on upper surface of the conductive bumps 48. Then, the resist layer 47 and the conductive layer 46 underneath the resist layer 47 are removed by using the adhesive layer 49 as an etching mask, as shown in FIG. 4I′. Subsequently, a reflow process is performed.

In the present invention, the insulating layer 41 is first formed on the core circuit board 40 having conductive circuits 402 and then the conductive circuit terminals 44a of small width is formed on the insulating layer 41. Further, conductive bumps are formed in the openings 450 of the insulating protection layer 45 that are a little larger in width than the terminals 44a. Thus, the size of the conductive bumps is decreased and spacing between the conductive bumps is reduced.

Compared with the prior art that forms conductive bumps on electrically connecting pads, the present invention can form fine pitch conductive bumps on terminals of conductive circuits, thereby avoiding the prior art drawbacks such as process bottleneck due to high requirement of registration and difficulty of forming fine pitch conductive bumps due to reduced registration resolution on the other hand. Moreover, since the conductive bumps of the present invention completely cover the terminals, contact area between them is increased, thereby increasing the bonding force and pulling/pushing forces between the conductive bumps and the circuit board. Meanwhile, since the present invention uses a conductive layer as a current conductive path in electroplating process for forming conductive bumps, low cost material such as copper can be used in the electroplating process to speed up fabrication process. Moreover, the present invention avoids bridge and short circuit effect by decreasing the use of solder materials. Furthermore, the electroplating process of the present invention overcomes the drawbacks of the conventional stencil printing method.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabrication method of a conductive bump structure of a circuit board, comprising the steps of:
providing the circuit board with conductive circuits formed on at least one surface thereof, and forming an insulating protection layer on the circuit board, wherein the insulating protection layer is formed with a plurality of openings to expose terminals of the conductive circuits on the circuit board;
forming a conductive layer on the insulating protection layer and in the openings thereof;
forming a resist layer on the conductive layer, the resist layer having a plurality of openings to expose portions of the conductive layer corresponding to the terminals of the conductive circuits; and
forming conductive bumps by electroplating in the openings of the resist layer and on the portions of the conductive layer corresponding to the terminals of the conductive circuits.

2. The fabrication method of claim 1 further comprising the steps of:
removing the resist layer and the conductive layer underneath the resist layer; and
forming an adhesive layer on the conductive bumps to completely cover exposed surfaces of the conductive bumps respectively.

3. The fabrication method of claim 1 further comprising the steps of:
performing an electroplating process to form an adhesive layer on upper surfaces of the conductive bumps respectively;
removing the resist layer and the conductive layer underneath the resist layer; and
performing a reflow process.

4. The fabrication method of claim 1, wherein the circuit board is fabricated by steps comprising:
forming an insulating layer on a core circuit board, the core circuit board being formed with electrically connecting pads and conductive circuits on a surface thereof, and forming a plurality of openings in the insulating layer to expose the electrically connecting pads;
forming a conductive layer on the insulating layer and in the openings thereof;
forming a resist layer on the conductive layer, and patterning the resist layer to form a plurality of openings to expose portions of the conductive layer underneath the resist layer, wherein at least one of the openings of the resist layer corresponds in position to the electrically connecting pads; and
performing an electroplating process to form conductive circuits in the openings of the resist layer and form conductive vias in the openings of the insulating layer, so as to electrically connect the conductive circuits in the openings of the resist layer to the electrically connecting pads of the core circuit board.

5. The fabrication method of claim 1, wherein the openings of the insulating protection layer has a size larger than a width of the conductive circuits.

6. The fabrication method of claim 1, wherein the conductive bumps are made of a material selected from the group consisting of copper (Cu), tin (Sn), silver (Ag), lead (Pb) and alloy thereof.

7. The fabrication method of claim 2, wherein the adhesive layer is made of a material selected from the group consisting of Cu, Sn, Pb, Ag, nickel (Ni), gold (Au), platinum (Pt), phosphorous (P) and alloy thereof.

8. The fabrication method of claim 3, wherein the adhesive layer is made of a material selected from the group consisting of Cu, Sn, Pb, Ag, Ni, Au, Pt, P and alloy thereof.

9. The fabrication method of claim 2, wherein the adhesive layer is made of an organic solderability preservative (OSP).

10. The fabrication method of claim 3, wherein the adhesive layer is made of an organic solderability preservative (OSP).

11. A conductive bump structure of a circuit board, comprising:
conductive bumps formed on terminals of conductive circuits on a surface of the circuit board; and
an adhesive layer formed on the conductive bumps respectively.

12. The conductive bump structure of claim 11, wherein the circuit board further comprises an insulating protection layer having openings to expose the terminals of the conductive circuits.

13. The conductive bump structure of claim 12, wherein the openings of the insulating protection layer has a size larger than a width of the conductive circuits.

14. The conductive bump structure of claim 11, wherein the conductive bumps completely cover the terminals of the conductive circuits.

15. The conductive bump structure of claim 11, wherein the adhesive layer is formed on upper surfaces of the conductive bumps respectively.

16. The conductive bump structure of claim 11, wherein the adhesive layer completely covers exposed surfaces of the conductive bumps respectively.

17. The conductive bump structure of claim 11, wherein the conductive bumps are made of a material selected from the group consisting of Cu, Sn, Ag, Pb and alloy thereof.

18. The conductive bump structure of claim 11, wherein the adhesive layer is made of a material selected from the group consisting of Cu, Sn, Pb, Ag, Ni, Au, Pt, P and alloy thereof.

19. The conductive bump structure of claim 11, wherein the adhesive layer is made of an organic solderability preservative (OSP).
